(19) United States
(12) Patent Application Publication
(10) Pub. No.: US 2019/0268516 A1
(43) Pub. Date: Aug. 29, 2019

(54) MINIATURE LED ARRAY AND ELECTRONIC DEVICE USING THE SAME

(71) Applicant: HON HAI PRECISION INDUSTRY CO., LTD., New Taipei (TW)

(72) Inventors: TE-EN TSENG, New Taipei (TW); TZU-HSIANG LAN, New Taipei (TW)

(21) Appl. No.: 16/048,500

(22) Filed: Jul. 30, 2018

(30) Foreign Application Priority Data
Feb. 27, 2018 (TW) 107106576

(51) Int. Cl. H04N 5/225; H01L 25/075; G06F 1/16; H05B 33/08

(52) U.S. Cl. CPC H04N 5/2256; H01L 25/0753; G06F 1/1686; H04M 1/026; G06F 1/1626; G06F 1/1647; H05B 33/0872

(57) ABSTRACT

An MICRO LED array on an electronic device is arranged on the same side as a front lens of the device. The MICRO LED array includes a display area and a supplemental lighting area. The display area displays images or text, and the light supplementing area provides illumination and/or supplemental light of the scene in front of the device. A sensor of the device senses characteristics of current shooting environment and a controller controls an adjusting unit to adjust the display area and the light supplementing area according to the sensed characteristics of the current shooting environment and certain stored parameters, to achieve optimal lighting and coloration in images of the scene captured by the device.

### CROSS-REFERENCE TO RELATED APPLICATIONS

This application claims priority to Taiwanese Patent Application No. 107106576 filed on Feb. 27, 2018, the contents of which are incorporated by reference herein.

### FIELD

The instant disclosure relates generally to displays.

### BACKGROUND

Mobile phones and panel computers are widely used. People often take photos using a camera of a mobile terminal. However, a flash lamp is often set on the back of the mobile terminal, not on the display screen side, the flash lamp is not available to assist the front camera set on the display screen side. Thus, there is room for improvement within the art.

### BRIEF DESCRIPTION OF THE DRAWINGS

Implementations of the present technology will now be described, by way of example only, with reference to the attached figures.

FIG. 1 illustrates a schematic diagram of an LED array.

FIG. 2 is a schematic diagram of a first embodiment of an LED assembly in the LED array of FIG. 1.

FIG. 3 is a schematic diagram of a second embodiment of the LED assembly in the LED array of FIG. 1.

FIG. 4 is an another schematic diagram of an LED array.

FIG. 5 illustrates a schematic diagram of an electronic device.

FIG. 6 is a block diagram of one embodiment of the electronic device of FIG. 5.

FIG. 7 is a flowchart of an image shooting method in one embodiment.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “outside” refers to a region that is beyond the outermost confines of a physical object. The term “inside” indicates that at least a portion of a region is partially contained within a boundary formed by the object. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series, and the like.

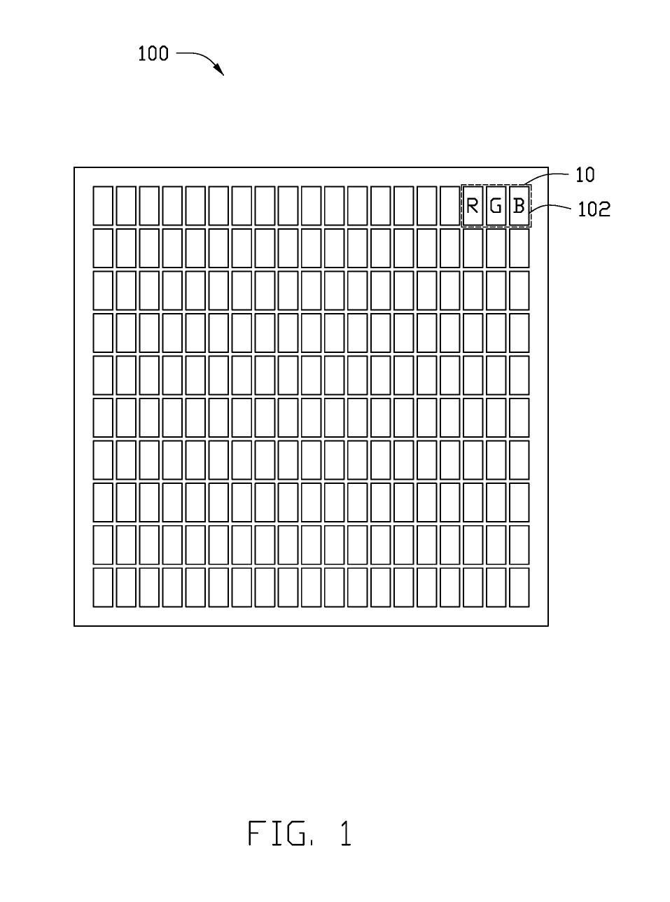

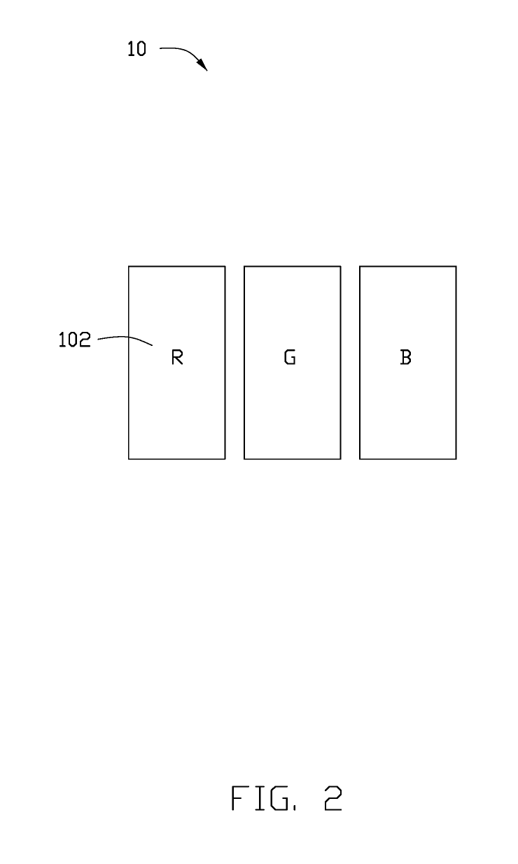

FIG. 1 illustrates a schematic diagram of an LED array 100. The LED array 100 can be set on a display screen of mobile terminal, such as smart phone or panel computer. The LED array 100 includes a number of micro LED assemblies 10. FIG. 2 illustrates the number of LED assemblies 10. The number of LED assemblies 10 are arranged in parallel as a rectangular LED array 100. Each LED assembly 10 is able to emit light with different brightnesses and different color temperatures. In at least one embodiment, each LED assembly 10 includes at least three three-primary-color micro LEDs 102. Each micro LED 102 can be controlled to adjust its brightness and color temperature. Thus, the brightness and color temperature of the LED assembly 10 can be adjusted by adjusting the brightness and color temperature of each micro LED 102. In at least one embodiment, the color temperature is a unit of measurement representing the sum of the color components of the light. The tones of images taken under different color temperatures of light are different.

In at least one embodiment, each LED assembly 10 includes three three-primary-color micro LEDs 102 which are arranged in parallel. The three-primary-color micro LEDs 102 can be red light micro LED, green light micro LED, and blue light micro LED. In at least one exemplary embodiment, the micro LED 102 has a long strip structure, and the micro LED mainly emits light in an axial direction. The brightness and color temperature of each LED assembly 10 can be adjusted by adjusting the brightness and color temperature of each micro LED 102.

In another embodiment, the number of the micro LEDs 102 in each LED assembly 10 is not limited to three, and the number of the micro LEDs 102 in each LED assembly 10 can be changed based on user's requirements. In at least one embodiment, to increase color gamut, the LED assembly 10 not only includes red light micro LED, green light micro LED, and blue light micro LED, but also includes white light micro LED or yellow light micro LED.

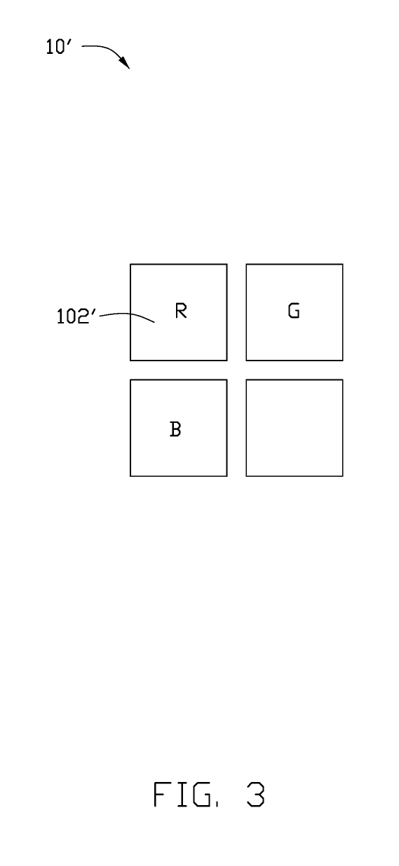

FIG. 3 illustrates a schematic diagram of a second embodiment of an LED assembly, LED assembly 10′. The LED assembly 10′ includes three three-primary-color micro LEDs 102′ and one white color micro LED′ 102′ or one yellow color micro LED 102′. The micro LED 102′ has a square structure. The four square micro LEDs 102′ constitute a large square LED assembly 10′. The four micro LEDs 102′ can respectively emit red light, green light, blue light, white light, or yellow light.

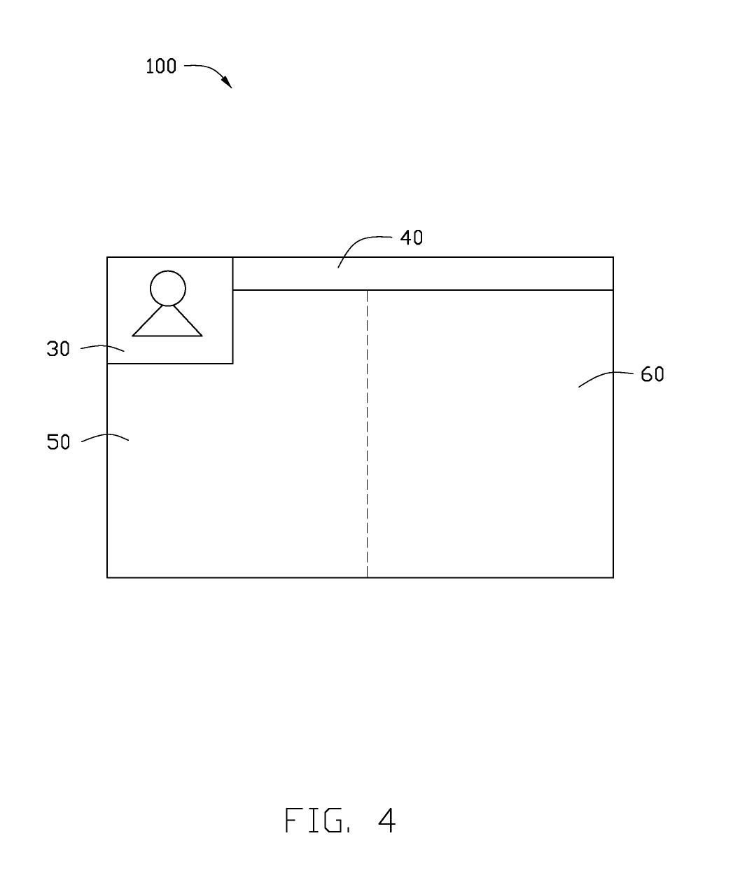

The LED array 100 can be used to display images and/or text, or can provide illumination and/or supplemental light (refer to FIG. 4). In at least one embodiment, the LED array 100 is divided into a first display area 30, a second display area 40, a first light supplementing area 50, and a second light supplementing area 60. The first display area 30 is an image display area and is used to display images. The second display area 40 is a text display area and is used to display text. The first light supplementing area 50 and the second light supplementing area 60 are used to provide illumination and/or additional light (light supplement). In at least embodiment, the first light supplementing area 50 and the second light supplementing area 60 provide light with different brightnesses and color temperatures. In at least one embodiment, the size of the first light supplementing area 50 and the second light supplementing area 60 can be adjusted based on user's requirements.

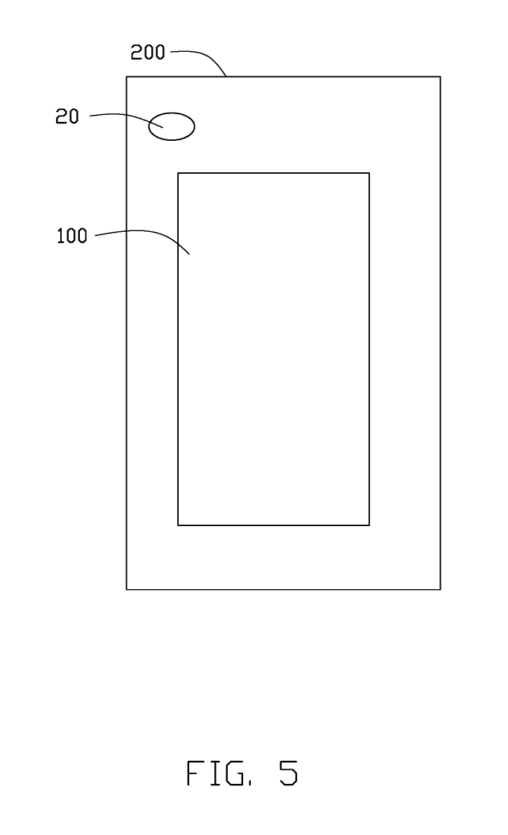

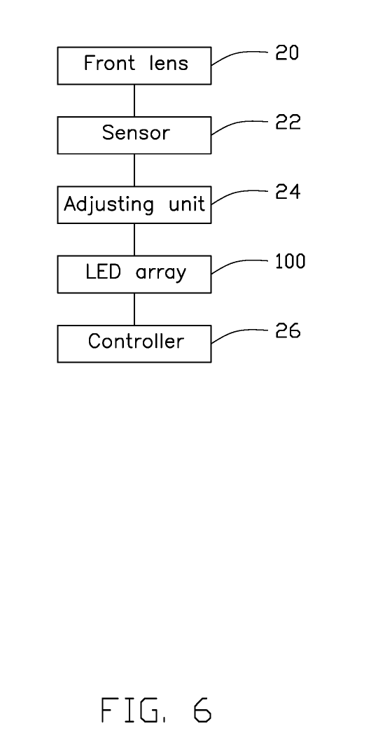

FIG. 5 and FIG. 6 illustrate an electronic device 200. The electronic device 200 includes the LED array 100, a front lens 20, a sensor 22, an adjusting unit 24, and a controller 26. The LED array 100 is set on the display screen (not shown) of the electronic device 200. The front lens 20 and the LED array 100 are arranged on the same side of the electronic device 200, and are available for user to shoot light-assisted images by the front lens 20 of the electronic device 200.

The sensor 22 is electronically connected to the front lens 20 and the adjusting unit 24. The sensor 22 is used to sense the current shooting environment. In at least one embodiment, when the front lens 20 shoots images, the sensor 22 is triggered by the front lens 20 to sense the characteristics of the current shooting environment, and acquires the characteristics of current shooting environment. The characteristics of current shooting environment can be brightness and color temperature. The sensor 22 further transmits the acquired characteristics of current shooting environment to the adjusting unit 24. In at least one embodiment, the adjusting unit 22 can be an optical sensor.

The adjusting unit 24 is electronically connected to the LED array 100. The adjusting unit 24 adjusts brightness and color temperature of the LED array 100 based on the characteristics of current shooting environment, to make the brightness and color temperature of the LED array 100 match with the shooting environment of the front lens 20 according to certain parameters. In at least one embodiment, the adjusting unit 24 adjusts the brightness and color temperature of the LED array 100 by adjusting brightness and color temperature of each micro LED 102, by turning on or off each micro LED 102. Thus, the adjusted brightness and color temperature of the LED array 100 match with the shooting environment of the front lens 20. For example, the adjusting unit 24 can increase the brightness of the LED array 100 to increase the lighting of current shooting environment. The adjusting unit 24 can adjust color temperature of the LED array 100 to balance color temperature of current shooting environment, to cause the brightness of the LED array 100 to be sufficient and/or to cause the color temperature of the LED array 100 to be realistic. Thus, the shooting effect of the front lens 20 is enhanced.

The controller 26 is electronically connected to the LED array 100. The controller 26 adjusts size of the first display area 30, size of the second display area 40, size of the first light supplementing area 50, and size of the second light supplementing area 60 according to the display content of the electronic device 200. The characteristics of current shooting environment sensed by the sensor 22 and the certain parameters can be referenced. In at least one embodiment, the controller 26 can be a central processing unit (CPU), a microprocessor, or other data processor chip that performs functions of the electronic device.

When the sensor 22 detects that the brightness of current shooting environment is sufficient, for example when the brightness of current shooting environment is larger than a preset value, the controller 26 adjust the sizes of the first display area 30, the second display area 40, the first light supplementing area 50, and the second light supplementing area 60. For example, the controller 26 can increase the sizes of the first display area 30 and the second display area to fully display image or text. When the sensor 22 detects that the brightness of current shooting environment is insufficient, for example when the brightness of current shooting environment is less than a preset value, the controller 26 increases the sizes of the first light supplementing area 50 and the second light supplementing area 60 and makes the respective sizes greater than the sizes of the first display area 30 and the second display area 40, to provide supplemental light.

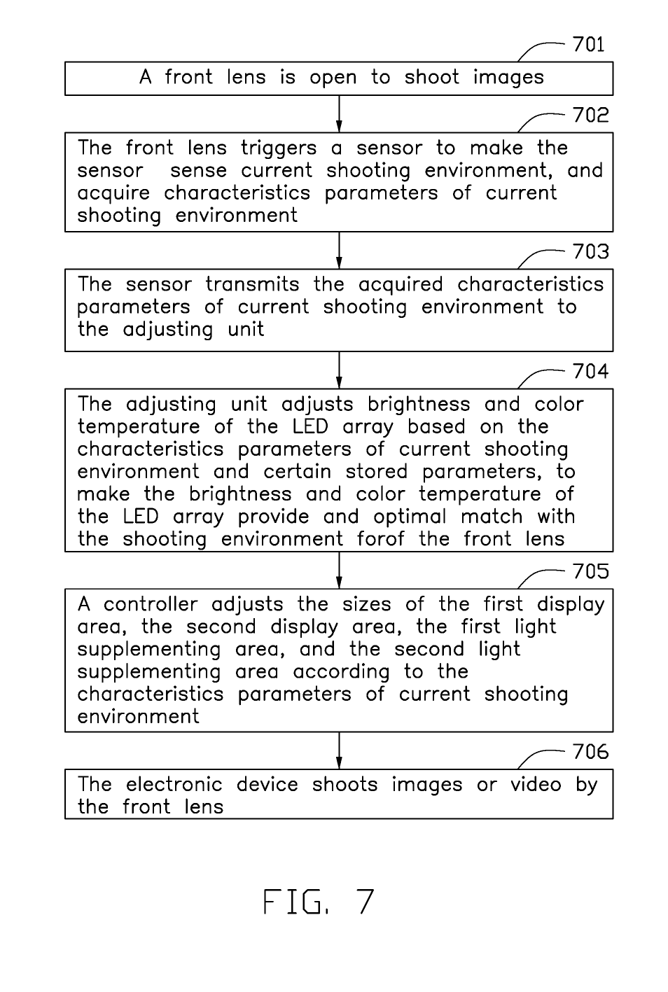

FIG. 7 illustrates a flowchart of one embodiment of image shooting method. The image shooting method is applied in the electronic device 200. The method is provided by way of example, as there are a variety of ways to carry out the method. The method described below can be carried out using the configurations illustrated in FIGS. 1-6, for example, and various elements of these figures are referenced in explaining the example method. Each block shown in FIG. 7 represents one or more processes, methods, or subroutines carried out in the example method. Furthermore, the illustrated order of blocks is by example only and the order of the blocks can be changed. Additional blocks may be added or fewer blocks may be utilized, without departing from this disclosure. The example method can begin at block 701.

At block 701, the front lens 20 is open to shoot images.

At block 702, the front lens 20 triggers the sensor 22 to sense current shooting environment, and acquire the characteristics of current shooting environment. In at least one embodiment, the characteristics of current shooting environment can be brightness and color temperature of the scene.

At block 703, the sensor 22 transmits the acquired characteristics of current shooting environment to the adjusting unit 24. In at least one embodiment, the adjusting unit 22 can be an optical sensor.

At block 704, the adjusting unit 24 adjusts brightness and color temperature of the LED array 100 based on the characteristics of current shooting environment and certain stored parameters, to make the brightness and color temperature of the LED array 100 provide and optimal shooting environment for the front lens 20.

In at least one exemplary embodiment, the adjusting unit 24 adjusts the brightness and color temperature of the LED array 100 by adjusting brightness and color temperature of each micro LED 102, by turning on or off each micro LED 102. Thus, the adjusted brightness and color temperature of the LED array 100 provides a better shooting environment for the front lens 20. For example, the adjusting unit 24 can increase the brightness of the LED array 100 to supplement brightness of current shooting environment, and/or the adjusting unit 24 can adjust color temperature of the LED array 100 to provide realistic colors in the current shooting environment. Thus the brightness of the LED array 100 can render sufficient lighting and realistic coloring. Thus, the shooting effect of the front lens 20 is enhanced.

At block 705, the controller 26 adjusts the sizes of the first display area 30, the second display area 40, the first light supplementing area 50, and the second light supplementing area 60 according to the display content of the electronic device 200 and the characteristics of current shooting environment sensed by the sensor 22 and the certain stored parameters.

When the sensor 22 detects that the brightness of current shooting environment is sufficient, for example when the brightness of current shooting environment is larger than a preset value, the controller 26 adjust size of the first display area 30, the second display area 40, the first light supplementing area 50, and the second light supplementing area 60. For example, the controller 26 increase the size of the first display area 30 and the second display area to fully display image or text. When the sensor 22 detects that the brightness of current shooting environment is insufficient, for example when the brightness of current shooting environment is less than a preset value, the controller 26 increases the size of the first light supplementing area 50 and the second light supplementing area 60 to make the size of the first light supplementing area 50 and the second light supplementing area 60 larger than the size of the first display area 30 and the second display area 40. This provides supplemental light for front lens 20 in shooting images.

At block 706, the electronic device shoots images or video by the front lens 20.

In at least one embodiment, the LED array 100 is divided into a first display area 30, a second display area 40, a first light supplementing area 50, and a second light supplementing area 60. The first display area 30 is an image display area and is used to display images. The second display area 40 is a text display area and is used to display text. The first light supplementing area 50 and the second light supplementing area 60 are used to provide illumination and/or supplemental light. In at least embodiment, the first light supplementing area 50 and the second light supplementing area 60 can provide light with different brightnesses and color temperatures.

The embodiments shown and described above are only examples. Even though numerous characteristics and advantages of the present disclosure have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

What is claimed is:

1. A LED array comprising:
a display area configured to display images or text; and
a light supplementing area configured to provide illumination and/or supplemental light.

2. The LED array of claim 1, wherein the LED array comprises a plurality of LED assemblies, the plurality of LED assemblies are arranged in parallel.

3. The LED array of claim 2, wherein each LED assembly comprises at least three three-primary-color micro LEDs.

4. The LED array of claim 3, wherein each micro LED can be turned on, turned off, and controlled to adjust brightness and color temperature of each micro LED to cause brightness and color temperature of each LED assembly to be adjusted.

5. The LED array of claim 3, wherein each micro LED can be a red light micro LED, a green light micro LED, or a blue light micro LED.

6. The LED array of claim 3, wherein each micro LED has a long strip structure, and each micro LED emits light in an axial direction.

7. The LED array of claim 1, wherein a size of the display area and a size of the light supplementing area can be adjusted.

8. The LED array of claim 7, wherein the display area comprises a first display area and a second display area, the first display area displays images, the second display area display text, the light supplementing area comprises a first light supplementing area and a second light supplementing area, each of the first light supplementing area and the second light supplementing area provide supplemental light with different brightnesses and color temperatures from each other.

9. An electronic device comprising:
a front lens configured to shoot images;
a LED array arranged on the same side of the electronic device with the front lens, wherein, the LED array comprises a display area and a light supplementing area, the display area displays images or text, the light supplementing area provides illumination and/or supplemental light;
a sensor configured to sense current shooting environment and acquire characteristics of the current shooting environment;
an adjusting unit coupled to the LED array;
a controller coupled to the front lens, the sensor, and the adjusting unit and configured to control the adjusting unit to adjust the display area and the light supplementing area according to the characteristics of the current shooting environment.

10. The electronic device of claim 9, wherein the characteristics of the current shooting environment comprises brightness.

11. The electronic device of claim 10, wherein when the brightness of current shooting environment is less than a preset value, the controller controls the adjusting unit to increases the size of the light supplementing area and make the size of the light supplementing area larger than the size of the display area to provide supplemental light.

12. The electronic device of claim 11, the controller controls the adjusting unit to adjust color temperature of the LED array.

13. The electronic device of claim 9, wherein the MICRO LED array comprises a plurality of MICRO LED assemblies, the plurality of MICRO LED assemblies are arranged in parallel.

14. The electronic device of claim 13, wherein each LED assembly comprises at least three three-primary-color micro LEDs.

15. The electronic device of claim 14, wherein each micro LED can be turned on, turned off, and controlled to adjust brightness and color temperature of each micro LED to cause brightness and color temperature of each LED assembly to be adjusted.

16. The electronic device of claim 14, wherein each micro LED can be a red light micro LED, a green light micro LED, or a blue light micro LED.

17. The electronic device of claim 14, wherein each micro LED has a long strip structure, and each micro LED emits light in an axial direction.

18. The electronic device of claim 14, wherein the display area comprises a first display area and a second display area, the first display area displays images, the second display area display text, the light supplementing area comprises a first light supplementing area and a second light supplementing area, each of the first light supplementing area and the second light supplementing area provide supplemental light with different brightnesses and color temperatures from each other.
